(19) United States
(12) Patent Application Publication
(10) Pub. No.: US 2021/0159438 A1
(43) Pub. Date: May 27, 2021

(54) QUANTUM DOT ARCHITECTURES FOR FLUORESCENCE DONOR-ASSISTED OLED DEVICES

(71) Applicant: Nanoco Technologies Ltd., Manchester (GB)

(72) Inventors: Nigel PICKETT, Manchester (GB); James HARRIS, Manchester (GB); Nathalie GRESTY, Manchester (GB); Stuart STUBBS, Manchester (GB)

(21) Appl. No.: 17/045,904

(22) PCT Filed: Apr. 5, 2019
(86) PCT No.: PCT/GB2019/051016

§ 371 Date: Oct. 7, 2020

Related U.S. Application Data
(60) Provisional application No. 62/656,072, filed on Apr. 11, 2018.

(51) Int. Cl. H01L 51/50

(52) U.S. Cl. CPC H01L 51/502; H01L 51/5016; H01L 51/5024

(57) ABSTRACT

An emissive layer of an electroluminescent device, such as an electroluminescent display device, includes a host matrix and a two-dopant system dispersed in the host matrix. The two-dopant system has a fluorescent emitter dopant and an emissive donor-assistant dopant. The emissive donor-assistant dopant can be a fluorescence donor-assistant dopant or a phosphorescence donor-assistant dopant. The physical distance between the fluorescent emitter dopant and the emissive donor-assistant dopant can be controlled by using various capping ligands, which are bound to a surface of the fluorescent emitter dopant.

### CROSS REFERENCE TO RELATED APPLICATION

This application claims the benefit of U.S. Provisional Application No. 62/656,072, filed Apr. 11, 2018, the contents of which are incorporated by reference herein in their entirety.

### FIELD OF THE INVENTION

The present invention relates to electroluminescent display devices and methods of making electroluminescent display devices. More particularly, the present invention relates to electroluminescent display devices which utilize a two-dopant system for fluorescence. More particularly, the present invention relates to electroluminescent display devices which utilize a two-dopant system for fluorescence wherein the two dopants are quantum dots and emissive (fluorescence or phosphorescence) donors.

### BACKGROUND OF THE DISCLOSURE

### Semiconductor Nanomaterials

There has been substantial interest in the preparation and characterization of compound semiconductors consisting of particles with dimensions in the order of 2-100 nm, often referred to as quantum dots (QDs) and/or nanoparticles. Studies in this field have focused mainly on the size-tunable electronic, optical and chemical properties of nanoparticles. Semiconductor nanoparticles are gaining interest due to their potential in commercial applications as diverse as biological labeling, solar cells, catalysis, biological imaging, and light-emitting diodes.

Two fundamental factors (both related to the size of the individual semiconductor nanoparticles) are primarily responsible for their unique properties. The first is the large surface-to-volume ratio: as a particle becomes smaller, the ratio of the number of surface atoms to those in the interior increases. This leads to the surface properties playing an important role in the overall properties of the material. The second factor is that, for many materials (including semiconductor nanoparticles), the electronic properties of the material change with particle size. Moreover, because of quantum confinement effects, the band gap typically becomes gradually larger as the size of the nanoparticle decreases. This effect is a consequence of the confinement of an “electron in a box,” giving rise to discrete energy levels similar to those observed in atoms and molecules, rather than a continuous band as observed in the corresponding bulk semiconductor material. Semiconductor nanoparticles tend to exhibit a narrow bandwidth emission that is dependent upon the particle size and composition of the nanoparticle material. The first excitonic transition (band gap) increases in energy with decreasing particle diameter.

Semiconductor nanoparticles of a single semiconductor material, referred to herein as “core nanoparticles,” along with an outer organic passivating layer, tend to have relatively low quantum efficiencies due to electron-hole recombination occurring at defects and dangling bonds situated on the nanoparticle surface that can lead to non-radiative electron-hole recombinations.

One method to eliminate defects and dangling bonds on the inorganic surface of the nanoparticle is to grow a second inorganic material (typically having a wider band-gap and small lattice mismatch to that of the core material) on the surface of the core particle to produce a “core-shell” particle. Core-shell particles separate carriers confined in the core from surface states that would otherwise act as non-radiative, recombination centers. One example is ZnS grown on the surface of CdSe cores. Another approach is to prepare a core-multishell structure where the “electron-hole” pair is completely confined to a single shell layer consisting of a few monolayers of a specific material such as a quantum dot-quantum well structure. Here, the core is typically a wide bandgap material, followed by a thin shell of narrower bandgap material, and capped with a further wide-bandgap layer. An example is CdS/HgS/CdS grown using substitution of Hg for Cd on the surface of the core nanocrystal to deposit just a few monolayers of HgS that is then overgrown by monolayers of CdS. The resulting structures exhibit clear confinement of photo-excited carriers in the HgS layer.

The most-studied and prepared semiconductor nanoparticles to date have been so-called “II-VI materials,” for example, ZnS, ZnSe, CdS, CdSe, and CdTe, as well as core-shell and core-multi shell structures incorporating these materials. However, cadmium and other restricted heavy metals used in conventional QDs are highly toxic elements and are of major concern in commercial applications.

Other semiconductor nanoparticles that have generated considerable interest include nanoparticles incorporating Group III-V and Group IV-VI materials, such as GaN, GaP, GaAs, InP, and InAs. Due to their increased covalent nature, III-V and IV-VI highly crystalline semiconductor nanoparticles are more difficult to prepare and much longer annealing times are usually required. However, there are now reports of III-VI and IV-VI materials being prepared in a similar manner to that used for the II-VI materials.

### Organic Light-Emitting Diodes (OLEDs)

In recent years, electroluminescent display devices, specifically organic light emitting diodes (OLEDs), have been of great interest within the display industry. An OLED is a light-emitting diode (LED) in which a film of organic compounds is placed between two conductors, which film emits light in response to excitation, such as an electric current. OLEDs are useful in displays, such as television screens, computer monitors, mobile phones, and tablets. A problem inherent in OLED displays is the limited lifetime of the organic compounds. OLEDs which emit blue light, in particular, degrade at a significantly increased rate as compared to green or red OLEDs.

OLED materials rely on the radiative decay of molecular excited states (excitons) generated by recombination of electrons and holes in a host transport material. Two types of excited states are created when charge recombines in an OLED—bright singlet excitons (with a total spin of 0) and dark triplet excitons (with a total spin of 1)—but only the singlets directly give light which fundamentally limits external OLED efficiencies. Spin statistics states that one singlet exciton is generated for every three triplet excitons after the recombination of holes and electrons in organic semiconductor materials. The efficiency of OLEDs can therefore be substantially increased if the non-emissive triplets can be utilized.

To date, OLED material design has focused on harvesting the remaining energy from the normally dark triplets. Recent work to create efficient phosphors, which emit light from the normally dark triplet state, have resulted in green and red OLEDs. Other colors, such as blue, however, require higher energy excited states which accelerate the degradation process of the OLED.

The fundamental limiting factor to the triplet-singlet transition rate is a value of the parameter |H_{fi}/Δ|², where H_{fi} is the coupling energy due to hyperfine or spin-orbit interactions, and Δ is the energetic splitting between singlet and triplet states. Traditional phosphorescent OLEDs rely on the mixing of singlet and triplet states due to spin-orbital (SO) interaction, increasing H_{fi}, and affording a lowest emissive state shared between a heavy metal atom and an organic ligand. This results in energy harvesting from all higher singlet and triplet states, followed by phosphorescence (relatively short-lived emission from the excited triplet). The shortened triplet lifetime reduces triplet exciton annihilation by charges and other excitons. Recent work by others suggests that the limit to the performance of phosphorescent materials has been reached.

It is thought that the solution processability of OLED devices may lead to a low production cost once mass production has been fully established, and can enable the fabrication of devices on flexible substrates, leading to new technologies such as roll-up displays. In an OLED device, the pixels emit directly, enabling a greater contrast ratio and wider viewing angle compared to liquid crystal displays (LCDs). Further, in contrast to LCDs, OLED displays do not require a backlight, allowing a true black when the OLED is switched off. OLEDs also offer faster response times than LCDs. However, OLED devices typically suffer from poor stability and lifetimes, owing to the lifespans of the organic emissive materials. Blue OLEDs currently display much lower external quantum efficiencies than green and red OLEDs. Further, OLEDs often suffer from broad emission; for display applications narrower emission is desirable to provide better colour purity. Thus, there is a need for a solution-processable emissive device with good stability and lifetime and improved blue emission.

### SUMMARY OF THE INVENTION

The present invention relates to an emissive layer of an electroluminescent display device, the emissive layer comprising: a host matrix; and a two-dopant system dispersed in the host matrix, the two-dopant system comprising: a fluorescent emitter dopant; and an emissive donor-assistant dopant.

The fluorescent emitter dopant may be a quantum dot. The quantum dot may be a core-shell quantum dot. The core of the core-shell quantum dot may comprise indium.

The emissive donor-assistant dopant may be any one of a fluorescence donor-assistant dopant and a phosphorescence donor-assistant dopant.

The emissive donor-assistant dopant may generate triplet excitons and convert the triplet excitons through reverse intersystem crossing (RISC).

The singlet excitons may be transferred from the emissive donor-assistant dopant to the fluorescent emitter dopant.

The physical distance between the fluorescent emitter dopant and the emissive donor-assistant dopant may be dependent upon the length of a capping ligand bound to a surface of the fluorescent emitter dopant. The capping ligand may be entropic. The capping ligand may be an inorganic ligand.

The emissive donor-assistant dopant may be a metal nanoparticle.

The emissive donor-assistant dopant may comprise a lanthanide.

The emissive donor-assistant dopant may be an organic fluorophore.

The emissive donor-assistant dopant may be a nucleic acid fluorophore.

The emissive donor-assistant dopant may be a fluorescent protein.

The emissive donor-assistant dopant may be a fluorescent small molecule.

The emissive donor-assistant dopant may be a dendrimer.

The emissive donor-assistant dopant may be a phosphorescent material comprising iridium or platinum.

The emissive donor-assistant dopant may be a thermally activated delayed fluorescence (TADF) molecule.

The emissive donor-assistant dopant may be a light-emitting polymer.

### BRIEF DESCRIPTION OF THE DRAWINGS

FIG. 1 is a schematic illustration of an exemplary organic light emitting diode (OLED) device structure in accordance with various aspects of the present disclosure;

FIG. 2 depicts an energy level diagram of a TADF molecule;

FIG. 3 depicts an energy level diagram of a two-dopant system in accordance with various aspects of the present disclosure; and

FIG. 4 is a schematic illustration of alternative bases for critical distance (rₒ) determination in accordance with various aspects of the present disclosure.

### DETAILED DESCRIPTION

The following description of the embodiments is merely exemplary in nature and is in no way intended to limit the subject matter of the present disclosure, their application, or uses.

As used throughout, ranges are used as shorthand for describing each and every value that is within the range. Any value within the range can be selected as the terminus of the range. Unless otherwise specified, all percentages and amounts expressed herein and elsewhere in the specification should be understood to refer to percentages by weight.

For the purposes of this specification and appended claims, unless otherwise indicated, all numbers expressing quantities, percentages or proportions, and other numerical values used in the specification and claims, are to be understood as being modified in all instances by the term “about.” The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent, alternatively ±5 percent, and alternatively ±1 percent of the given numeric value provided such a deviation does not alter the end function or result of the value. Accordingly, unless indicated to the contrary, the numerical parameters set forth in this specification and attached claims are approximations that can vary depending upon the desired properties sought to be obtained by the present invention.

It is noted that, as used in this specification and the appended claims, the singular forms “a,” “an,” and “the,” include plural references unless expressly and unequivocally limited to one referent. As used herein, the term “include” and its grammatical variants are intended to be non-limiting, such that recitation of items in a list is not to the exclusion of other like items that can be substituted or added to the listed items. For example, as used in this specification and the following claims, the terms “comprise” (as well as forms, derivatives, or variations thereof such as “comprising” and “comprises”), “include” (as well as forms, derivatives, or variations thereof such as “including” and “includes”) and “has” (as well as forms, derivatives, or variations thereof such as “having” and “have”) are inclusive (i.e., open-ended) and do not exclude additional elements or steps. Accordingly, these terms are intended to not only cover the recited element(s) or step(s), but may also include other elements or steps not expressly recited. Furthermore, as used herein, the use of the terms “a” or “an” when used in conjunction with an element may mean “one,” but it is also consistent with the meaning of “one or more,” “at least one,” and “one or more than one.” Therefore, an element preceded by “a” or “an” does not, without more constraints, preclude the existence of additional identical elements.

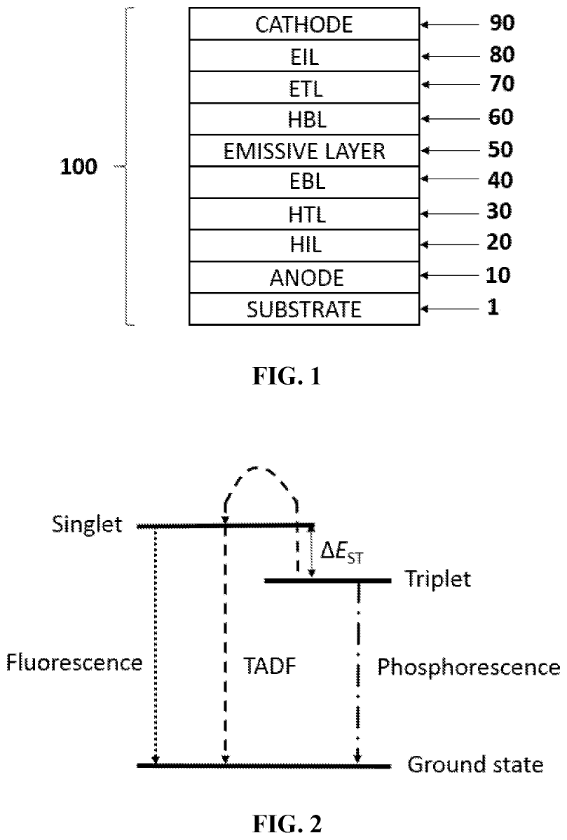

FIG. 1 is a schematic illustration of an exemplary organic light emitting diode (OLED) device structure. The OLED 100 includes a substrate 1, an anode 10, a hole injection layer (HIL) 20, a hole transport layer (HTL) 30, an electron blocking layer (EBL) 40, an emissive layer 50, a hole blocking layer (HBL) 60, an electron transport layer (ETL) 70, and electron injection layer (EIL) 80 and a cathode 90. In some instances, the OLED device structure of FIG. 1 can contain additional layers or omit one or more of the shown layers. In OLED device structures, the emissive layer 50 comprises a fluorescent material dispersed in a host matrix. One specific type of fluorescent material is an organic molecule which exhibits thermally activated delayed fluorescence (TADF). In the present disclosure, the emissive layer 50 comprises a two-dopant system comprising a quantum dot fluorescent emitter dopant and a fluorescence/phosphorescence donor-assistant dopant dispersed in a host matrix such as, for example, 3,3-di(9H-carbazol-9-yl)biphenyl (mCBP).

FIG. 2 depicts an energy level diagram of a TADF molecule. In a TADF molecule, upon excitation, triplet state excitons are generated. Generally, triplet excitons generated from emitters such as platinum and iridium complexes non-radiatively decay from the triplet state to the ground state and do not contribute to light emission. In TADF molecules, on the other hand, the triplet excitons are upconverted to singlet state excitons via reverse intersystem crossing (RISC) due to the small energy gap (ΔE_{ST}) between the singlet and triplet states, and light emission can be extracted as delayed fluorescence from the singlet state. In TADF molecules, ΔE_{ST} is provided by the absorption of thermal energy.

In accordance with various aspects of the present disclosure, a two-dopant system comprising a quantum dot fluorescent emitter dopant and a fluorescence/phosphorescence donor-assistant dopant is provided for use in emissive layers of electroluminescent display devices. Embodiments of the present disclosure are designed to combine the exciton harvesting capabilities of fluorescence donors to achieve near unity internal quantum efficiency, with energy transfer of harvested excitons to QDs with high photoluminescence quantum yield, to achieve hyperfluorescent, narrow emission quantum dot devices. The narrow, pseudo-Gaussian emission of QDs may lead to better colour purity and efficiency as compared to organic fluorophores. QD fluorescence emission is tuneable by tuning the particle size and composition, whereas organic fluorophores generally exhibit broad and specific emission profiles. Additionally, the fluorescence quantum yields (QYs) of QDs are typically higher than those of organic fluorophores. In some instances, the fluorescence donor can be a TADF molecule.

In some instances, a two-dopant system comprising a quantum dot fluorescent emitter dopant and a phosphorescence donor-assistant dopant is provided for use in electroluminescent display devices.

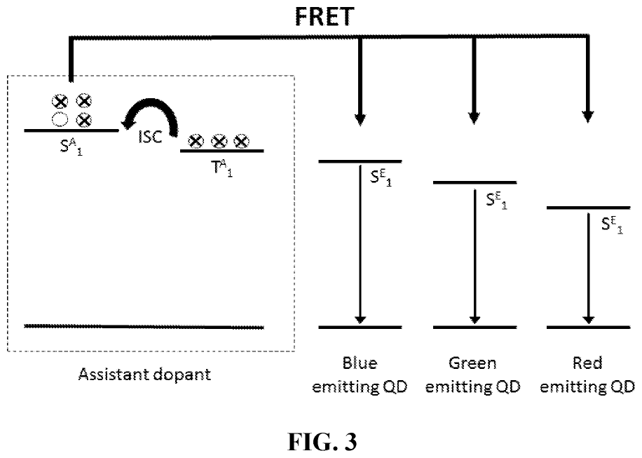

When an emissive layer includes a fluorescence donor and QDs, singlet excitons on the fluorescence donor are resonantly transferred to the QDs via Förster resonance energy transfer (FRET). Light is then emitted from the singlet state of the QDs. FIG. 3 depicts an energy level diagram of a two-dopant system according to various aspects of the present disclosure. When an emissive layer includes only TADF compounds the triplet excitons are upconverted to singlet state excitons via reverse intersystem crossing (RISC) due to the small energy gap (ΔEₛₜ) between the singlet and triplet states, and light emission can be extracted as delayed fluorescence from the singlet state as described above. When a TADF compound is in the presence of QDs, however, the singlet excitons of the fluorescence donor are resonantly transferred to a singlet state of the QDs via Förster resonance energy transfer (FRET). Light is then emitted as delayed fluorescence from the singlet state of the QDs. When the emissive layer contains a phosphorescence donor and QDs, singlet and triplet excitons on the phosphorescence donor have a non-zero oscillatory strength and so can be resonantly transferred to the QDs via Förster resonance energy transfer (FRET). Light is then emitted from the singlet state of the QDs.

In some instances, the QDs can be blue-emitting QDs. In other instances, the QDs can be green-emitting QDs. In yet other instances, the QDs can be red-emitting QDs. In yet other instances, the QDs can be any combination of blue-, green- and red-emitting QDs. In yet other instances, the QDs can be UV-emitting QDs. In yet other instances, the QDs can be IR-emitting QDs. In yet other instances, the QDs can be tuned to emit at any wavelength ranging from the UV to the IR regions of the electromagnetic spectrum, depending on the application. The particular donor is not limiting. In some instances, the donor is a fluorescence donor. In some instances, the fluorescence donor is a TADF molecule. TADF molecules used in accordance with various aspects of the present disclosure can include, for example, those described in U.S. Pat. Nos. 9,502,668, 9,634,262, 9,660,198, 9,685,615, U.S. Patent Application Publication No. 2016/0372682, U.S. Patent Application Publication No. 2016/0380205, and U.S. Patent Application Publication No. 2017/0229658, the entire contents of which are incorporated by reference herein. In some instances, the donor is a phosphorescence donor.

To optimize the performance of two-dopant systems in electroluminescent devices, such as electroluminescent displays, it may be advantageous to design QDs having various qualities. First, the QDs should have high oscillator strength. Second, the QDs should be fabricated to have high FRET with the fluorescent or phosphorescent donor. Third, the QDs should be fabricated to be strong absorbers. Finally, the QDs should be fabricated to exhibit a short excited state lifetime. One of ordinary skill in the art will recognize that the above are not necessarily the only qualities that may be optimized in systems according to the present disclosure.

### Maximization of FRET

In accordance with various aspects of the present disclosure, singlet excitons of the fluorescence/phosphorescence donor are resonantly transferred to a singlet state of the QDs via FRET. The better the spectral overlap between the fluorescence/phosphorescence donor emission and the QD absorption, the better the FRET efficiency and thus the longer the distance over which the energy can be carried. A critical distance for the near-field dipole-dipole coupling mechanism, FRET, can be calculated from the spectral overlap of a fluorescence/phosphorescence donor and a QD (an “absorbance acceptor”) according to the Förster mechanism [Förster, Th., Ann. Phys. 437, 55 (1948)]. To maximize the efficiency of FRET between the fluorescence/phosphorescence donor and the QD, the critical distance should be determined. The critical distance, r₀, between the fluorescence/phosphorescence donor and the QD is the distance at which the FRET efficiency is 50%, and is defined Equation 1: [Y. Q. Zhang and X. A. Cao, Appl. Phys. Lett., 2010, 97, 253115].

$${r}_{0}^{2} = \frac{9}{8 π} \frac{{c}^{4}}{{n}^{4}} {κ}^{2} {η}_{D} \int \frac{{S}_{D} ( ω ) {σ}_{A} ( ω )}{{ω}^{4}} d ω$$

where c is the speed of light in a vacuum, n is the refractive index of the material, κ² is an orientation factor, η_{D} is the photoluminescence (PL) quantum efficiency of the fluorescence/phosphorescence donor, S_{D} is the normalised PL spectrum of the TADF molecule, and σ_{A} is the QD absorption cross-section. The better the spectral overlap between the fluorescence/phosphorescence donor and the QD absorption, the better the transfer efficiency and thus the longer the distance over which the energy can be carried.

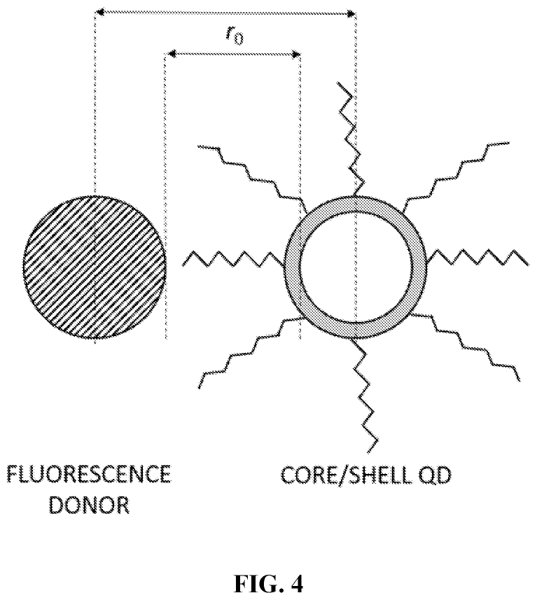

FIG. 4 is a schematic illustration of alternative bases for rₒ determination. In some instances, r₀ can be measured from the centre of the fluorescence/phosphorescence donor to the centre of the QD core (from which emission takes place in a Type I QD). In other instances, r₀ can be measured from the edge of the fluorescence/phosphorescence donor to the edge of the QD core.

While the fluorescence/phosphorescence donor is shown in FIG. 4 as a circle or sphere, one of ordinary skill in the art can readily appreciate that the shape of any particular fluorescence donor is dependent upon its chemical structure. Additionally, while the QD is shown as a being spherical, one of ordinary skill in the art can readily appreciate that the shape of the QDs used in accordance with various aspects of the present disclosure can vary as described herein. QDs used in accordance with various aspects of the present disclosure can be any one of core, core-shell, core-multishell or quantum dot-quantum well (QD-QW) QDs. If r₀ is measured from the edge of the fluorescence/phosphorescence donor to the edge of the QD core, a QD-QW architecture may be desirable. A QD-QW comprises a narrower band gap first shell sandwiched between a core and a second shell of a wider band gap material, with emission coming from the first shell. Therefore, the distance between the edge of the fluorescence/phosphorescence donor and edge of the core in a core/shell QD may be greater than that between the edge of the fluorescence/phosphorescence donor and the edge of the first shell in a QD-QW.

QDs used in accordance with varying aspects of the present disclosure can have a size ranging from 2-100 nm and include core material comprising:

IIA-VIA (2-16) material, consisting of a first element from group 2 of the periodic table and a second element from group 16 of the periodic table and also including ternary and quaternary materials and doped materials. Nanoparticle material includes but is not restricted to: MgS, MgSe, MgTe, CaS, CaSe, CaTe, SrS, SrSe, SrTe, BaS, BaSe, BaTe;

IIB-VIA (12-16) material consisting of a first element from group 12 of the periodic table and a second element from group 16 of the periodic table and also including ternary and quaternary materials and doped materials. Nanoparticle material includes but is not restricted to: ZnS, ZnSe, ZnTe, CdS, CdSe, CdTe, HgS, HgSe, HgTe;

II-V material consisting of a first element from group 12 of the periodic table and a second element from group 15 of the periodic table and also including ternary and quaternary materials and doped materials. Nanoparticle material includes but is not restricted to: Zn₃P₂, Zn₃As₂, Cd₃P₂, Cd₃As₂, Cd₃N₂, Zn₃N₂;

III-V material consisting of a first element from group 13 of the periodic table and a second element from group 15 of the periodic table and also including ternary and quaternary materials and doped materials. Nanoparticle material includes but is not restricted to: BP, AlP, AlAs, AlSb; GaN, GaP, GaAs, GaSb; InN, InP, InAs, InSb, AlN, BN;

III-IV material consisting of a first element from group 13 of the periodic table and a second element from group 14 of the periodic table and also including ternary and quaternary materials and doped materials. Nanoparticle material includes but is not restricted to: B₄C, Al₄C₃, Ga₄C;

II-VI material consisting of a first element from group 13 of the periodic table and a second element from group 16 of the periodic table and also including ternary and quaternary materials. Nanoparticle material includes but is not restricted to: Al₂S₃, Al₂Se₃, Al₂Te₃, Ga₂S₃, Ga₂Se₃, GeTe; In₂S₃, In₂Se₃, Ga₂Te₃, In₂Te₃, InTe;

IV-VI material consisting of a first element from group 14 of the periodic table and a second element from group 16 of the periodic table, and also including ternary and quaternary materials and doped materials. Nanoparticle material includes but is not restricted to: PbS, PbSe, PbTe, SnS, SnSe, SnTe;

V-VI material consisting of a first element from group 15 of the periodic table and a second element from group 16 of the periodic table, and also including ternary and quaternary materials and doped materials. Nanoparticle material includes but is not restricted to: Bi₂Te₃, Bi₂Se₃, Sb₂Se₃, Sb₂Te₃; and

Nanoparticle material consisting of a first element from any group in the transition metal of the periodic table, and a second element from group 16 of the periodic table and also including ternary and quaternary materials and doped materials. Nanoparticle material includes but is not restricted to: NiS, CrS, CuInS₂, CuInSe₂, CuGaS₂, CuGaSe₂, CuInₓGa₁₋ₓS_{y}Se_{2-y} (where 0≤x≤1 and 0≤y≤2), AgInS₂.

By the term doped nanoparticle for the purposes of specifications and claims, refer to nanoparticles of the above and a dopant comprised of one or more main group or rare earth elements, this most often is a transition metal or rare earth element, such as but not limited to zinc sulfide with manganese, such as ZnS nanoparticles doped with Mn⁺.

The term “ternary material,” for the purposes of specifications and claims, refers to QDs of the above but a three component material. The three components are usually compositions of elements from the as mentioned groups Example being (ZnₓCdₓ₋₁S)ₘLₙ nanocrystal (where L is a capping agent).

The term “quaternary material,” for the purposes of specifications and claims, refer to nanoparticles of the above but a four-component material. The four components are usually compositions of elements from the as mentioned groups Example being (ZnₓCdₓ₋₁S_{y}Se_{y-1})ₘLₙ nanocrystal (where L is a capping agent).

The material used on any shell or subsequent numbers of shells grown onto the core particle in most cases will be of a similar lattice type material to the core material i.e. have close lattice match to the core material so that it can be epitaxially grown on to the core, but is not necessarily restricted to materials of this compatibility. The material used on any shell or subsequent numbers of shells grown on to the core present in most cases will have a wider bandgap then the core material but is not necessarily restricted to materials of this compatibility. The materials of any shell or subsequent numbers of shells grown on to the core can include material comprising:

IIA-VIA (2-16) material, consisting of a first element from group 2 of the periodic table and a second element from group 16 of the periodic table and also including ternary and quaternary materials and doped materials. Nanoparticle material includes but is not restricted to: MgS, MgSe, MgTe, CaS, CaSe, CaTe, SrS, SrSe, SrTe;

IIB-VIA (12-16) material consisting of a first element from group 12 of the periodic table and a second element from group 16 of the periodic table and also including ternary and quaternary materials and doped materials. Nanoparticle material includes but is not restricted to: ZnS, ZnSe, ZnTe, CdS, CdSe, CdTe, HgS, HgSe, HgTe;

II-V material consisting of a first element from group 12 of the periodic table and a second element from group 15 of the periodic table and also including ternary and quaternary materials and doped materials. Nanoparticle material includes but is not restricted to: Zn₃P₂, Zn₃As₂, Cd₃P₂, Cd₃As₂, Cd₃N₂, Zn₃N₂;

III-V material consisting of a first element from group 13 of the periodic table and a second element from group 15 of the periodic table and also including ternary and quaternary materials and doped materials. Nanoparticle material includes but is not restricted to: BP, AlP, AlAs, AlSb; GaN, GaP, GaAs, GaSb; InN, InP, InAs, InSb, AlN, BN;

I-IV material consisting of a first element from group 13 of the periodic table and a second element from group 14 of the periodic table and also including ternary and quaternary materials and doped materials. Nanoparticle material includes but is not restricted to: B₄C, Al₄C₃, Ga₄C;

III-VI material consisting of a first element from group 13 of the periodic table and a second element from group 16 of the periodic table and also including ternary and quaternary materials. Nanoparticle material includes but is not restricted to: Al₂S₃, Al₂Se₃, Al₂Te₃, Ga₂S₃, Ga₂Se₃, In₂S₃, In₂Se₃, Ga₂Te₃, In₂Te₃;

IV-VI material consisting of a first element from group 14 of the periodic table and a second element from group 16 of the periodic table and also including ternary and quaternary materials and doped materials. Nanoparticle material includes but is not restricted to: PbS, PbSe, PbTe, SnS, SnSe, SnTe;

V-VI material consisting of a first element from group 15 of the periodic table and a second element from group 16 of the periodic table, and also including ternary and quaternary materials and doped materials. Nanoparticle material includes but is not restricted to: Bi₂Te₃, Bi₂Se₃, Sb₂Se₃, Sb₂Te₃; and

Nanoparticle material consisting of a first element from any group in the transition metal of the periodic table, and a second element from group 16 of the periodic table and also including ternary and quaternary materials and doped materials. Nanoparticle material includes but is not restricted to: NiS, CrS, CuInS₂, CuInSe₂, CuGaS₂, CuGaSe₂, CuInₓGa₁₋ₓS_{y}Se_{2-y} (where 0≤x≤1 and 0≤y≤2), AgInS₂.

Fluorescence/phosphorescence donors used in accordance with varying aspects of the present disclosure may include, but are not restricted to:

QDs such those described above;

Metal nanoparticles, including noble metal nanoparticles, including but not restricted to: Ag, Au;

TADF molecules, for example, those described in U.S. Pat. Nos. 9,502,668, 9,634,262, 9,660,198, 9,685,615, U.S. Patent Application Publication No. 2016/0372682, U.S. Patent Application Publication No. 2016/0380205, and U.S. Patent Application Publication No. 2017/0229658, the entire contents of which are incorporated by reference herein, and including but not restricted to: bis[3,5-di(9H-carbazol-9-yl)phenyl]diphenylsilane; 2,5,8,11-tetra-tert-butylperylene; 10,10′,10″-(4,4′,4″-phosphoryltris(benzene-4,1-diyl))tris(10H-phenoxazine); 10-(4-(4,6-diphenyl-1,3,5-triazin-2-yl)phenyl)-9,9-dimethyl-9,10-dihydroacridine; 10-phenyl-10H,10′H-spiro[acridine-9,9′-anthracen]-10′-one; 3,6-dibenzoyl-4,5-di(1-methyl-9-phenyl-9H-carbazoyl)-2-ethynylbenzonitrile; 9,9′,9″-(5-(4,6-diphenyl-1,3,5-triazin-2-yl)benzene-1,2,3-triyl) tris(9H-carbazole); 2,4,6-tris[3-(diphenylphosphinyl)phenyl]-1,3,5-triazine; 9,9′-(4,4′-sulfonylbis(4,1-phenylene))bis(3,6-di-tert-butyl-9H-carbazole); 10,10′-(4,4′-(4-phenyl-4H-1,2,4-triazole-3,5-diyl)bis(4,1-phenylene))bis(10H-phenoxazine); bis(4-(9H-3,9′-bicarbazol-9-yl)phenyl)methanone; 10,10′-(4,4′-sulfonylbis(4,1-phenylene))bis(9,9-dimethyl-9,10-dihydroacridine); 9′-[4-(4,6-diphenyl-1,3,5-triazin-2-yl)phenyl]-3,3″,6,6″-tetraphenyl-9,3′:6′,9″-ter-9H-carbazole; 9′-[4-(4,6-diphenyl-1,3,5-triazin-2-yl)phenyl]-9,3′:6′,9″-ter-9H-carbazole; 9,9′-(5-(4,6-diphenyl-1,3,5-triazin-2-yl)-1,3-phenylene)bis(9H-carbazole); 9,9′,9″,9′″-((6-phenyl-1,3,5-triazine-2,4-diyl)bis(benzene-5,3,1-triyl))tetrakis(9H-carbazole); 9,9′-(4,4′-sulfonylbis(4,1-phenylene))bis(3,6-dimethoxy-9H-carbazole); 9-(4-(4,6-diphenyl-1,3,5-triazin-2-yl)phenyl)-3′,6′-diphenyl-9H-3,9′-bicarbazole; 10-(4,6-diphenyl-1,3,5-triazin-2-yl)-10H-phenoxazine; 9-(4-(4,6-diphenyl-1,3,5-triazin-2-yl)phenyl)-9H-carbazole; 2,5,8,11-tetra-tert-butylperylene; 2,3,4,6-tetra(9H-carbazol-9-yl)-5-fluorobenzonitrile; 9,10-bis[N,N-di-(p-tolyl)-amino]anthracene; 2,5-bis(4-(10H-phenoxazin-10-yl)phenyl)-1,3,4-oxadiazole; 3-(9,9-dimethylacridin-10(9H)-yl)-9H-xanthen-9-one; 1,4-bis(9,9-dimethylacridan-10-yl-pphenyl)-2,5-bis(ptolyl-methanoyl)benzene; 1,4-bis(9,9-phenoxazin-10-yl-p-phenyl)-2,5-bis(p-tolylmethanoyl)-benzene; 5,10-bis(4-(1-phenyl-1H-benzo[d]imidazol-2-yl)phenyl)-5,10-dihydrophenazine; 10,10′-(4,4′-sulfonylbis(4,1-phenylene))bis(10H-phenoxazine); 1,3,5-tris(4-(diphenylamino)phenyl)-2,4,6-tricyanobenzene; 9,9′,9″-(5-(4,6-diphenyl-1,3,5-triazin-2-yl)benzene-1,2,3-triyl) tris(3,6-dimethyl-9H-carbazole); 4,4″-di-10H-phenoxazin-10-yl[1,1′: 2′,1″-terphenyl]-4′,5′-dicarbonitrile; 2[-(2-pyridinyl)-9-[3-(2-pyridinyloxy) phenyl]-9H-carbazole]palladium; 2′-(4,6-diphenyl-1,3,5-triazin-2-yl)-N,N-diphenylbiphenyl-2-amine; 5-chloro-2,4,6-tris(3,6-di-tert-butyl-9H-carbazol-9-yl)isophthalonitrile; dibenzo([f,f′]-4,4′,7,7′-tetraphenyl)diindeno[1,2,3-cd:1′,2′,3′-lm]perylene; 2,3,5,6-tetrakis[3,6-bis(1,1-dimethylethyl)-9H-carbazol-9-yl]benzonitrile; 7,10-bis(4-(diphenylamino)phenyl)-2,3-dicyanopyrazino phenanthrene; 2,8-di-tert-butyl-5,11-bis(4-tert-butylphenyl)-6,12-diphenyltetracene; dibenzo([f,f′]-4,4′,7,7′-tetraphenyl)diindeno[1,2,3-cd:1′,2′,3′-lm]perylene; 2-[4-(diphenylamino) phenyl]-10,10-dioxide-9H-thioxanthen-9-one; 2-(9-phenyl-9H-carbazol-3-yl)-10,10-dioxide-9H-thioxanthen-9-one;

Lanthanide compounds, including lanthanide phosphors and lanthanide complexes. Lanthanide phosphors include but are not restricted to: Ce³⁺-doped phosphors; Eu²⁺-doped phosphors; Eu³⁺-doped phosphors; Pr³⁺-doped phosphors; Sm³⁺-doped phosphors; Tb³⁺-doped phosphors; Er³⁺-doped phosphors; Yb³⁺-doped phosphors; Nd³⁺-doped phosphors; Dy³⁺-doped phosphors. Lanthanide complexes include but are not restricted to: complexes incorporating Sm(III), Eu(III), Er(III), Tb(III), Dy(III), Nd(III), Ce(II) Pr(III), Yb(III);

Organic fluorophores including but not restricted to: xanthene derivatives: fluorescein; rhodamine; Oregon green; eosin; Texas red; cyanine derivatives: cyanine; indocarbocyanine; oxacarbocyanine; thiacarbocyanine; indocyanine green; merocyanine; squaraine derivatives and ring-substituted squaraines: Seta; SeTau; Square dyes; naphthalene derivatives: dansyl and prodan derivatives; coumarin derivatives; oxadiazole derivatives: pyridyloxazole; nitrobenzoxadiazole; benzoxadiazole; anthracene derivatives: anthraquinones; DRAQ5; DRAQ7; CyTRAK Orange; pyrene derivatives: cascade blue; Oxazine derivatives: Nile red, Nile blue, cresyl violet, oxazine 170; acridine derivatives: proflavin; acridine orange; acridine yellow; arylmethine derivatives: auramine; crystal violet; malachite green; tetrapyrrole derivatives: porphin, phthalocyanine, bilirubin;

Nucleic Acid Fluorophores;

Fluorescent proteins including but not restricted to: fluorescent monomers, fluorescent dimers, fluorescent trimers;

Fluorescent small molecules including but not restricted to: tris(8-hydroxyquinoline)aluminium (Alq₃); 2,2′,2″-(1,3,5-benzinetriyl)-tris(1-phenyl-1-H-benzimidazole) (TPBi); bis(8-hydroxy-2-methylquinoline)-(4-phenylphenoxy)aluminium (BAlq);

Light-emitting polymers including but not restricted to: bis(2-(3,5-dimethylphenyl)-4-propylpyridine)(2,2,6,6-tetramethylheptane-3,5-diketonate)iridium(III); bis(2-phenylpyridine)(acetylacetonate)iridium(III); fac-tris(2-phenylpyridine)iridium(III); N,N′-dimethyl-quinacridone; 2,3,6,7-tetrahydro-1,1,7,7,-tetramethyl-1H,5H,11H-10-(2-benzothiazolyl)quinolizino[9,9a,1gh]coumarin; 3-(2-benzothiazolyl)-7-(diethylamino)coumarin; 4,4″-di-10H-phenoxazin-10-yl[1,1′:2′,1″-terphenyl]-4′,5′-dicarbonitrile; 9,9′,9″-(5-(4,6-diphenyl-1,3,5-triazin-2-yl)benzene-1,2,3-triyl) tris(3,6-dimethyl-9H-carbazole); 3-(2-benzothiazolyl)-7-(diethylamino)coumarin; 2,3,6,7-tetrahydro-1,1,7,7,-tetramethyl-1H,5H,11H-10-(2-benzothiazolyl)quinolizino[9,9a,1gh]coumarin; N,N′-Dimethyl-quinacridone; fac-tris(2-phenylpyridine)iridium(III); bis(2-phenylpyridinexacetylacetonate)iridium(III); tris[2-(p-tolyl)pyridine]iridium(III); 9,10-bis[N,N-di-(p-tolyl)-amino]anthracene; 9,10-bis[phenyl(m-tolyl)-amino]anthracene; bis[2-(2-hydroxyphenyl)benzothiazolato]zinc(II); N10,N10,N10′,N10′-tetra-tolyl-9,9′-bianthracene-10,10′-diamine; N10,N10,N10′,N10′-tetraphenyl-9,9′-bianthracene-10,10′-diamine; N10,N10′-diphenyl-N10,N10′-dinaphthalenyl-9,9′-bianthracene-10,10′-diamine; fac-tris(2-(3-p-xylyl)phenyl)pyridine iridium(III); 2,5-bis(4-(10H-phenoxazin-10-yl)phenyl)-1,3,4-oxadiazole; bis(2-(naphthalen-2-yl)pyridinexacetylacetonate)iridium(III); tris(2-phenyl-3-methyl-pyridine)iridium; 4,4′-bis[4-(diphenylamino)styryl]biphenyl; bis(3,5-difluoro-2-(2-pyridyl)phenyl-(2-carboxypyridyl)iridium(III); 4,4′-bis[4-(di-p-tolylamino)styryl]biphenyl; 4,4′-Bis[4-(di-p-tolylamino)styryl]biphenyl; 2,5,8,11-tetra-tert-butylperylene; perylene; 4,4′-bis(9-ethyl-3-carbazovinylene)-1,1′-biphenyl; 4,4′-bis(9-ethyl-3-carbazovinylene)-1,1′-biphenyl; 2,5,8,11-tetra-tert-butylperylene; 1,4-bis[2-(3-N-ethylcarbazoryl)vinyl]benzene; 4,4′-bis[4-(di-p-tolylamino)styryl]biphenyl; 4-(di-p-tolylamino)-4′-[(di-p-tolylamino)styryl]stilbene; bis(3,5-difluoro-2-(2-pyridyl)phenyl-(2-carboxypyridyl)iridium(III); 4,4′-bis[4-(diphenylamino)styryl]biphenyl; 2,7-bis[4-(diphenylamino)styryl]-9,9-spirobifluorene; bis(2,4-difluorophenylpyridinato)tetrakis(1-pyrazolyl)borate iridium(lII); N,N′-bis(naphthalen-2-yl)-N,N′-bis(phenyl)-tris-(9,9-dimethylfluorenylene); 2,7-bis(2-[phenyl(m-tolyl)amino]-9,9-dimethyl-fluorene-7-yl)-9,9-dimethyl-fluorene; N-(4-((E)-2-(6-((E)-4-(diphenylamino)styryl)naphthalen-2-yl)vinyl)phenyl)-N-phenylbenzenamine; fac-iridium(UI)tris(1-phenyl-3-methylbenzimidazolin-2-ylidene-C,C2′); mer-iridium(III)tris(1-phenyl-3-methylbenzimidazolin-2-ylidene-C,C2′); 1-4-di-[4-(N,N-diphenyl)amino]styryl-benzene; 1,4-bis(4-(9H-carbazol-9-yl)styryl)benzene; bis(2-(2-hydroxyphenyl)-pyridine)beryllium; bis(2,4-difluorophenylpyridinatox5-(pyridin-2-yl)-1H-tetrazolate)iridium(III); fac-tris[(2,6-diisopropylphenyl)-2-phenyl-1H-imidazo[e]]iridium(II); 9-[4-(2-(7-(N,N-diphenylamino)-9,9-diethylflouren-2-yl)vinyl)phenyl]-9-phenyl-fluorene; mer-tris(1-phenyl-3-methylimidazolin-2-ylidene-C,C(2)′iridium(III); fac-tris(1,3-diphenyl-benzimidazolin-2-ylidene-C,C2′)iridium(III); 9-(9-phenylcarbazole-3-yl)-10-(naphthalene-1-yl)anthracene; 4,4′-(1E,1′E)-2,2′-(naphthalene-2,6-diyl)bis(ethene-2,1-diyl)bis(N,N-bis(4-hexylphenyl)aniline); bis(3,5-difluoro-4-cyano-2-(2-pyridyl)phenyl-(2-carboxypyridyl) iridium(III); bis[4-tert-butyl-2′,6′-difluoro-2,3′-bipyridine](acetylacetonate)iridium(III); 4,4′-bis(4-(9H-carbazol-9-yl)styryl)biphenyl; 10,10′-(4,4′-(4-Phenyl-4H-1,2,4-triazole-3,5-diyl)bis(4,1-phenylene))bis(10H-phenoxazine); N5,N5,N9,N9-tetraphenylspiro[benzo[c]fluorene-7,9′-fluorene]-5,9-diamine; 10,10′-Bis(3,5-bis(trifluoromethyl)phenyl)-9,9′-bianthracene; bis(3,4,5-trifluoro-2-(2-pyridyl)phenyl-(2-carboxypyridyl)iridium(lII); N5,N9-diphenyl-N5,N9-di-m-tolylspiro[benzo[c]fluorene-7,9′-fluorene]-5,9-diamine; 6-methyl-2-(4-(9-(4-(6-methylbenzo[d]thiazol-2-yl)phenyl)anthracen-10-yl)phenyl)benzo[d]thiazole; 10-Phenyl-10H,10′H-spiro[acridine-9,9′-anthracen]-10′-one; tris(2-(4,6-difuorophenyl)pyridine)iridium(III); 10-(4-(4,6-diphenyl-1,3,5-triazin-2-yl)phenyl)-9,9-dimethyl-9,10-dihydroacridine; 3,6-dibenzoyl-4,5-di(1-methyl-9-phenyl-9H-carbazoyl)-2-ethynylbenzonitrile; 2-(3-(3-methyl-2,3-dihydro-1H-imidazol-1-yl)phenoxy)-9-(pyridin-2-yl)-9H-carbazoleplatinum(II); bis(2-(3,5-dimethylphenyl)-4-phenylpyridinex2,2,6,6-tetramethylheptane-3,5-diketonate)iridium(III); bis(2-benzo[b]thiophen-2-yl-pyridinexacetylacetonate)iridium(III); 4-(dicyanomethylene)-2-tert-butyl-6-(1,1,7,7-tetramethyljulolidin-4-yl-vinyl)-4H-pyran; (E)-2-(2-(4-(dimethylamino)styryl)-6-methyl-4H-pyran-4-ylidene)malononitrile; (E)-2-(2-(4-(dimethylamino)styryl)-6-methyl-4H-pyran-4-ylidene)malononitrile; 4-(dicyanomethylene)-2-methyl-6-julolidyl-9-enyl-4H-pyran; 4-(dicyanomethylene)-2-methyl-6-(1,1,7,7-tetramethyljulolidyl-9-enyl)-4H-pyran; 4-(dicyanomethylene)-2-tert-butyl-6-(1,1,7,7-tetramethyljulolidin-4-yl-vinyl)-4H-pyran; tris(dibenzoylmethane)phenanthrolineeuropium(III); 5,6,11,12-tetraphenylnaphthacene; bis(2-benzo[b]thiophen-2-yl-pyridine)(acetylacetonate)iridium(III); bis[1-(9,9-dimethyl-9H-fluoren-2-yl)-isoquinoline](acetylacetonate)iridium(III); bis[2-(9,9-dimethyl-9H-fluoren-2-yl)quinoline](acetylacetonate)iridium(III); tris[4,4′-di-tert-butyl-(2,2′)-bipyridine]ruthenium(III)complex; 2,8-di-tert-butyl-5,11-bis(4-tert-butylphenyl)-6,12-diphenyltetracene; bis(2-phenylbenzothiazolatoxacetylacetonate)iridium(III); platinum(II) 5,10,15,20-tetraphenyltetrabenzoporphyrin; bis[2-(4-n-hexylphenyl)quinoline](acetylacetonate)iridium(HI); tris[2-(4-n-hexylphenyl)quinoline)]iridium(HI); tris[2-phenyl-4-methylquinoline)]iridium(III); bis(2-phenylquinolinex2-(3-methylphenyl)pyridinate)iridium(III); bis(2-(9,9-diethyl-fluoren-2-yl)-1-phenyl-1H-benzo[d]imidazolatoxactylacetonate)iridium(III); bis(2-phenylpyridinex3-(pyridin-2-yl)-2H-chromen-2-onate)iridium(III); bis(2-phenylquinoline)(2,2,6,6-tetramethylheptane-3,5-dionate)iridium(III); bis(phenylisoquinoline)(2,2,6,6-tetramethylheptane-3,5-dionate) iridium(III); (E)-2-(2-tert-butyl-6-(2-(2,6,6-trimethyl-2,4,5,6-tetrahydro-1H-pyrrolo[3,2,1-ij]quinolin-8-yl)vinyl)-4H-pyran-4-ylidene)malononitrile; bis[(4-n-hexylphenyl)isoquinoline](acetylacetonate)iridium(III); platinum(II) octaethylporphine; bis(2-methyldibenzo[f,h]quinoxalinexacetylacetonate)iridium(III); tris[2-(4-n-hexylphenyl)quinoline)]iridium(III); tris(2-(3-methylphenyl)-7-methyl-quinolato)iridium; iridium(III)bis(4-(4-tert-butylphenyl) thieno[3,2-c]pyridinato-N,C2′) acetylacetonate; bis[2-(2-methylphenyl)-7-methyl-quinoline](acetylacetonate)iridium(III); iridium(III) bis(2-(2,4-difluorophenyl)quinoline) picolinate; bis[2-(9-phenylcarbazol-2-yl)-benzothiazole] iridium(III) picolinate; tris[3-(2,6-dimethylphenoxy)-6-phenylpyridazine]iridium(III); bis[2-(3,5-dimethylphenyl)-4-methyl-quinoline](acetylacetonate)iridium(III); (E)-2-(2-(4-(dimethylamino)styryl)-1-ethylquinolin-4(1H)-ylidene)malononitrile; (E)-2-(2-(2-(7-(4-(bis(4-methoxyphenyl)amino)phenyl)-2,3-dihydrothieno[3,4-b][1,4]dioxin-5-yl)vinyl)-1-ethylquinolin-4(1H)-ylidene)malononitrile;

Dendrimers including but not restricted to: poly(amido amine), poly(propylene amine);

Phosphorescent materials based on iridium, including but not restricted to: bis[2-(4,6-difluorophenyl)pyridinato-C²,N](picolinato)iridium(III); tris[2-phenylpyridine]iridium(III); bis[2-(2-phenyl-N)phenyl-C](acetylacetonato)iridium(III); bis(2-benzo[b]thiophen-2-yl-pyridine)(acetylacetonate)iridium(III); bis(3,5-difluoro-2-(2-pyridyl)phenyl-(2-carboxypyridyl)iridium(III); bis(2-phenylpyridine)(acetylacetonate)iridium(III); fac-tris(2-phenylpyridine)iridium(III); fac-tris(2-phenylpyridine)iridium(IU); bis(2-phenylpyridine)(acetylacetonate)iridium(III); tris[2-(p-tolyl)pyridine]iridium(III); fac-tris(2-(3-p-xylyl)phenyl)pyridine iridium(III); bis(3,5-difluoro-2-(2-pyridyl)phenyl-(2-carboxypyridyl)iridium(III); bis(2,4-difluorophenylpyridinato)tetrakis(1-pyrazolyl)borate iridium(III); bis(3,5-difluoro-4-cyano-2-(2-pyridyl)phenyl-(2-carboxypyridyl)iridium(III); bis(2-benzo[b]thiophen-2-yl-pyridinexacetylacetonate)iridium(III); tris[2-(4-n-hexylphenyl)quinoline)]iridium(III); bis(2-(9,9-diethyl-fluoren-2-yl)-1-phenyl-1H-benzo[d]imidazolato)(actylacetonate)iridium(UI); tris[2-(4-n-hexylphenyl)quinoline)]iridium(III); iridium(III)bis(4-(4-tert-butylphenyl)thieno[3,2-c]pyridinato-N,C2′)acetylacetonate; and

Phosphorescent materials based on platinum, including but not restricted to: 2,3,7,8,12,13,17,18-octaethyl1-21H,23H-porphine platinum(II); bis[2-(2-thienyl)pyridine]platinum(II); bis[2-(5-trimethylsilanyl-2-thenyl)-pyridine]platinum(II); Pt(iqdz)₂ (where (iqdz)=isoquinolinyl indazole anion); platinum(II)[3,5-di(2-pyridinyl)toluene]phenoxide; Pt(ppy)₂ (where ppy=2-phenylpyridine anion); (ppy)Pt(acac) (where acac=acetylacetonate); (fppy)Pt(m-pz)₂Pt(fppy) (where fppy=2-(4′,6′-difluorophenyl)pyrinato-N,C2′; pz=pyrazolyl); platinum(II)[1,3-difluoro-4,6-di(2-pyridinyl)benzene]chloride; platinum(II)[2-4′6′-difluorophenyl)pyridine-N,C2′)(2,4-pentanedionato).

As illustrated in FIG. 4, the degree of separation or distance between the fluorescence/phosphorescence donor and a QD can be controlled by using QD capping ligands. Specifically, the longer the capping ligand, the greater the distance between the fluorescence/phosphorescence donor and the QD. Generally, a Lewis acid is used as a capping ligand.

In some instances, capping ligands used in accordance with various aspects of the present disclosure can be primary, secondary or tertiary amines or ammonium compounds having one or more linear or branched C₁-C₂₄ alkyl groups; or one or more C₃-C₁₈ aromatic, polycyclic aromatic, cycloalkane, cycloalkene, cycloalkyne, polycycloalkane, polycycloalkene, or polycycloalkyne groups. In some instances, capping ligands used in accordance with various aspects of the present disclosure can be primary, secondary or tertiary phosphines or phosphonium compounds having one or more linear or branched C₁-C₂₄ alkyl groups; or one or more C₃-C₁₈ aromatic, polycyclic aromatic, cycloalkane, cycloalkene, cycloalkyne, polycycloalkane, polycycloalkene, or polycycloalkyne groups. In some instances, capping ligands used in accordance with various aspects of the present disclosure can be a carboxylic acid having a linear or branched C₁-C₂₄ alkyl group; or a C₃-C₁₈ aromatic, polycyclic aromatic, cycloalkane, cycloalkene, cycloalkyne, polycycloalkane, polycycloalkene, or polycycloalkyne groups.

In some instances, capping ligands used in accordance with various aspects of the present disclosure can be an alcohol, a thiol (R—S—H), a selenol (R—Se—H) or a tellurium equivalent (R—Te—H) having a linear or branched C₁-C₂₄ alkyl group; or a C₃-C₁₈ aromatic, polycyclic aromatic, cycloalkane, cycloalkene, cycloalkyne, polycycloalkane, polycycloalkene, or polycycloalkyne groups. In some instances, capping ligands used in accordance with various aspects of the present disclosure can be an entropic ligand. As used herein, “entropic ligand” refers to a ligand having an irregularly branched alkyl chain. Examples of suitable entropic ligands include, but are not restricted to: irregularly branched thiols, for example, 2-methylbutanethiol, and 2-ethylhexanethiol; and irregularly branched alkanoic acids, for example, 4-methyloctanoic acid, 4-ethyloctanoic acid, 2-butyloctanoic acid, 2-heptyldecanoic acid, and 2-hexyldecanoic acid. Entropic ligands may improve nanoparticle processability, while retaining or improving their performance in devices.

In some instances, inorganic ligands can be used in accordance with various aspects of the present disclosure as capping ligands by atomic passivation of QD surfaces with said inorganic ligands. Examples of suitable inorganic ligands include, but are not limited to metal halides, wherein the halide is any one Br, Cl, I or F, and the metal is any one of Al, Ti, V, Cr, Mn, Fe, Co, Ni, Nu, Zn, Mo, Pd, Ag, Cd, W, Pt. In some instances, zinc halides are preferred. In some instances, zinc chloride or zinc bromide are particularly preferred.

To maximise FRET, smaller QDs emitting at a given wavelength may be desirable. For example, QDs based on InP, which has a narrower bulk band gap and larger Bohr radius than core QDs such as CdSe, may be advantageous. An InP QD core emitting at, for example, 620 nm, will typically have a smaller diameter than a CdSe QD core emitting at the same wavelength.

### Maximization of QD Oscillator Strength

The oscillator strength of the band gap transition of a QD, f_{gap}, describes the probability of fluorescence. Thus, for two-dopant system applications it may be desirable to incorporate QDs having a high oscillator strength. In the strong quantum confinement regime, oscillator strength varies only weakly with QD size, since the electron and hole wave functions overlap completely, independently of particle size, [M. D. Leistikow, J. Johansen, A. J. Kettelarij, P. Lodahl and W. L. Vos, Phys. Rev. B, 2009, 79, 045301] whereas for QDs beyond the strong quantum confinement regime the oscillator strength should increase with increasing particle size. [K. E. Gong, Y. Zeng and D. F. Kelley, J. Phys. Chem. C, 2013, 117, 20268].

QDs comprising a core comprising, for example, InP and emitting within the visible spectrum would have a radius well within the strong confinement regime and the oscillator strength would therefore largely be independent of particle size. In some instances, the shape of the QD may influence oscillator strength. In some instances, the QDs can be substantially spherical or ovoid. In other instances, the QDs can be substantially conical. In yet other instances, the QDs can be substantially cylindrical. In yet other instances, the QDs can be substantially rod-shaped. In yet other instances, the QDs can be in the form or nanorods, nanotubes, nanofibers, nanosheets, dendrimers, stars, tetrapods, disks, or similar physical configurations.

### Increasing QD Absorption

A high QD absorption cross-section is desirable to maximise the FRET process. In quantum rods, for example the emission wavelength is controlled by the length of the short axis, and the absorption cross-section depends predominantly on volume. The absorption cross-section of a nanoparticle, αₐ, is defined in Equation 2:

$${α}_{a} ( ω ) = \frac{{n}_{b}}{n} {α}_{b} ( ω ) \vert f ( ω ) {\vert}^{2} V$$

where n_{b} and α_{b} are the refractive index and the absorption coefficient of the bulk semiconductor, respectively, n is the refractive index of the surrounding medium, |f( [symbol] ω)|² is the local-field factor, and V is the volume. Htoon et al. investigated the absorption cross-section of spherical (radius=2.3 nm) QDs compared with that of elongated nanoparticles, quantum rods, with the same radius but lengths of 22, 36 and 44 nm. [H. Htoon, J. A. Hollingworth, A. V. Malko, R Dickerson and V. I. Klimov, Appl. Phys. Lett., 2003, 82, 4776]. As well as the nanorods having a larger volume, |f( [symbol] ω)|² was found to almost twice as high for randomly oriented nanorods compared to the spherical nanoparticles. |f( [symbol] ω)|² can be increased yet further for aligned nanorods. Thus, a quantum rod architecture may be advantageous over a spherical QD geometry, in terms of increasing the QD absorption cross-section.

### Minimizing Excited State Lifetime

For efficient FRET, it is advantageous to minimize the excited state lifetime of QDs. Fundamentally, the excited state lifetime of a QD relates to the degree of confinement. The higher the overlap between the electron and hole, the stronger the confinement and the shorter the radiative lifetime. QD architectures that maximise the electron-hole overlap may be beneficial for two-dopant systems in electroluminescent devices. In some instances, for a given core size, increasing the shell thickness on said core decreases the excited state lifetime of the QD. However, as previously discussed, a core-shell quantum dot having a relatively thick shell may not be desirable, as the distance between the donor and the QD increases with increasing shell thickness. Thus, alternative methods to manipulate the degree of confinement in the QD may be required.

In a Type I core-shell QD, an abrupt offset of the energy levels may result in strong confinement, whereas compositional grading may lead to some delocalisation of the electrons and holes. For example, the confinement in an InP/ZnS QD, consisting of an InP core (bulk band gap, E_{g}, =1.34 eV) overcoated with a ZnS shell (E_{g}=3.54 eV (cubic); 3.91 eV (hexagonal)), will be stronger than that in an InP/ZnSe core-shell QD (ZnSe E_{g}=2.82 eV). An example of a compositionally graded Type I QD would be In₁₋ₓP_{1-y}ZnₓS_{y}, wherein x and y increase gradually from 0 at the centre of the QD to 1 at the outer surface of the QD.

Where core-multishell architectures are used, the relative thicknesses of the shells may influence the degree of confinement.

For core QDs of a particular material, the smaller the QD, the higher the overlap between the electron and hole and thus the shorter the radiative lifetime. Therefore, strategies to reduce the diameter of the QD core while maintaining a specific emission wavelength may be employed. This could include alloying a first semiconductor material with a second material having a smaller band gap at a similar lattice constant. For example, an InAsP nanoparticle, made by alloying InP with InAs, can emit at 630 nm and will have a smaller diameter than an InP nanoparticle emitting at the same wavelength. Also, for example, a CdSeS nanoparticle, made by alloying CdS with CdSe, can emit at 480 nm and will have a smaller diameter than a CdS nanoparticle emitting at the same wavelength.

In some instances, nanoparticle shape can affect the excited state lifetime. For example, the radiative lifetime of prolate CdSe QDs may be slightly shorter than that of spherical CdSe nanoparticles. [K. Gong, Y. Zang and D. F. Kelley, J. Phys. Chem. C, 2013, 117, 20268]. Thus, rod-shaped QDs, i.e. quantum rods, may offer a shorter excited state lifetime than spherical QDs. Herein, “quantum rod” is used to describe a quantum dot having lateral dimensions, x and y, and a length, z, wherein z>x,y. Alternatively, a shorter excited state lifetime may be provided by a 2-dimensional QD, wherein the quantum dot has lateral dimensions in the quantum confinement regime and a thickness between 1-5 monolayers.

Although the present invention and its objects, features and advantages have been described in detail, other embodiments are encompassed by the invention. Finally, those skilled in the art should appreciate that they can readily use the disclosed conception and specific embodiments as a basis for designing or modifying other structures for carrying out the same purposes of the present invention without departing from the scope of the invention as defined by the appended claims.

1. An emissive layer of an electroluminescent display device, the emissive layer comprising:
a host matrix; and
a two-dopant system dispersed in the host matrix, the two-dopant system comprising:
a fluorescent emitter dopant; and
an emissive donor-assistant dopant.

2. The emissive layer of claim 1, wherein the fluorescent emitter dopant is a quantum dot.

3. The emissive layer of claim 2, wherein the quantum dot is a core-shell quantum dot.

4. The emissive layer of claim 3, wherein the core of the core-shell quantum dot comprises indium.

5. The emissive layer of claim 1, wherein the emissive donor-assistant dopant is any one of a fluorescence donor-assistant dopant and a phosphorescence donor-assistant dopant.

6. The emissive layer of claim 1, wherein the emissive donor-assistant dopant generates triplet excitons and converts the triplet excitons to singlet excitons through reverse intersystem crossing (RISC).

7. The emissive layer of claim 1, wherein singlet excitons are transferred from the emissive donor-assistant dopant to the fluorescent emitter dopant.

8. The emissive layer of claim 1, wherein the physical distance between the fluorescent emitter dopant and the emissive donor-assistant dopant is dependent upon the length of a capping ligand bound to a surface of the fluorescent emitter dopant.

9. The emissive layer of claim 8, wherein the capping ligand is entropic.

10. The emissive layer of claim 8, wherein the capping ligand is an inorganic ligand.

11. The emissive layer of claim 1, wherein the emissive donor-assistant dopant is a metal nanoparticle.

12. The emissive layer of claim 1, wherein the emissive donor-assistant dopant comprises a lanthanide.

13. The emissive layer of claim 1, wherein the emissive donor-assistant dopant is an organic fluorophore.

14. The emissive layer of claim 1, wherein the emissive donor-assistant dopant is a nucleic acid fluorophore.

15. The emissive layer of claim 1, wherein the emissive donor-assistant dopant is a fluorescent protein.

16. The emissive layer of claim 1, wherein the emissive donor-assistant dopant is a fluorescent small molecule.

17. The emissive layer of claim 1, wherein the emissive donor-assistant dopant is a dendrimer.

18. The emissive layer of claim 1, wherein the emissive donor-assistant dopant is a phosphorescent material comprising iridium or platinum.
